(19) United States
(12) Patent Application Publication
(10) Pub. No.: US 2019/0228825 A1
(43) Pub. Date: Jul. 25, 2019

(54) VERTICAL RESISTOR BASED SRAM CELLS

(71) Applicant: Microsemi SoC Corp., San Jose, CA (US)

(72) Inventors: Volker Hecht, Barsinghausen (DE); John L. McCollum, Orem, UT (US)

(73) Assignee: Microsemi SoC Corp., San Jose, CA (US)

(21) Appl. No.: 16/248,705

(22) Filed: Jan. 15, 2019

Related U.S. Application Data
(60) Provisional application No. 62/642,453, filed on Mar. 13, 2018.
(60) Provisional application No. 62/621,498, filed on Jan. 24, 2018.

(51) Int. Cl. G11C 14/00

(52) U.S. Cl. CPC G11C 14/009; G11C 11/419; G11C 14/0054

(57) ABSTRACT

A static random-access memory (SRAM) cell includes a non-inverting logic element having an input and an output. A vertical resistor feedback device is connected between the output and the input of the non-inverting logic element.

### BACKGROUND

Single port SRAM cells are in wide use in the integrated circuit industry. A typical prior-art single port SRAM cell 10 is depicted in FIG. 1. SRAM cell 10 is coupled to a pair of complementary read-write (R/W) bit lines 12 and 14 and to a R/W word line 16.

The single port SRAM cell 10 is formed from two inverters 18 and 20 arranged in a feedback configuration where the output of inverter 18 is coupled to the input of inverter 20. The output of inverter 20 is coupled to the input of inverter 18.

A first access transistor 22 is connected between R/W bit line 12 and the common connection of the input of inverter 18 and the output of inverter 20. The first access transistor 22 has its gate connected to the R/W word line 16. A second access transistor 24 is connected between R/W bit line 14 and the common connection of the input of inverter 20 and the output of inverter 18. The second access transistor 24 has its gate connected to the R/W word line 16.

To read the contents of SRAM cell 10, a logic high level is presented on the R/W word line 16. This turns on both transistors 22 and 24, placing complementary output bits on complementary read-write (R/W) bit lines 12 and 14. To write to SRAM cell 10, complementary data bits are presented on complementary read-write (R/W) bit lines 12 and 14 and a logic high level is presented on the R/W word line 16. This turns on both transistors 22 and 24 as in the read mode, but the devices supplying the complementary data bits are stronger that either of inverters 18 and 20, forcing the states of the inverters 18 and 20, respectively, to assume the values of the complementary data bits presented on read-write (R/W) bit lines 12 and 14.

SRAM cell 10 requires six transistors, two each for inverters 18 and 20 in addition to the first and second access transistors 22 and 24. An array of SRAM cells 10 requires two bit lines 12 and 14 per column and one word line 16 per row.

There is a tight design window for SRAM cell 10. The inverters 18 and 20 must be weak enough to allow for a successful write by the devices supplying the complementary data bits over the resistance of bit lines 12 and 14 plus the access transistors. In addition, for read, the same inverters 18 and 20 must drive long bit lines 12 and 14. This tradeoff is not good for timing. In addition, use of the complementary pair of bit lines 12 and 14 requires complex sense-amplifier, precharge circuits and driver circuits.

Dual port SRAM cells are also in wide use in the integrated circuit industry. A typical prior-art dual port SRAM cell 30 is depicted in FIG. 2. As with the single port SRAM cell 10 of FIG. 1, SRAM cell 30 is coupled to a first pair of complementary read-write (R/W) bit lines 12 and 14 responsive to a R/W word line 16 through first and second access transistors 22 and 24. In addition SRAM cell 30 is coupled to a second pair of complementary read-write (R/W) bit lines 32 and 34 and responsive to a second R/W word line 36 through third and fourth access transistors 38 and 40, respectively.

SRAM cells 30 can employ two R/W ports (dual port) or one read port and one write port (2-port). Both of these configurations use the same SRAM cell 30, and differ only in that they require different access circuits to drive the bit lines 12, 14, 32, and 34 and word lines 16 and 36 to write and read data.

In the configuration shown in FIG. 2, to write to the SRAM cell 30 through port 1, complementary data bits are presented on complementary R/W bit lines 12 and 14 and the voltage on port 1 R/W word line 16 is raised to turn on access transistors 22 and 24. To read the SRAM cell 30 through port 1, the voltage on the port 1 R/W word line 16 is raised to turn on access transistors 22 and 24 and the complementary data is presented on complementary R/W bit lines 12 and 14. To write the SRAM cell 30 through port 1, complementary data bits are presented on complementary R/W bit lines 12 and 14, and the voltage on the port 1 R/W word line 16 is raised to turn on access transistors 22 and 24.

To write to the SRAM cell 30 through port 2, complementary data bits are presented on complementary R/W bit lines 32 and 34 and the voltage on the port 2 R/W word line 36 is raised to turn on access transistors 38 and 40. To read the SRAM cell 30 through port 2, the voltage on the port 2 R/W word line 36 is raised to turn on access transistors 38 and 40 and the complementary data is presented on complementary R/W bit lines 32 and 34.

SRAM cell 30 requires eight transistors, two each for inverters 18 and 20 in addition to the four access transistors 22, 24, 38, and 40. This is two more transistors than are required for SRAM 10 of FIG. 1. An array of SRAM cells 30 requires four R/W bit lines 12, 14, 32, and 34 per column and two R/W word lines 16 and 36 per row. The number of R/W bit lines and R/W word lines are doubled from the single port SRAM 10 of FIG. 1.

SRAM cell 30 has the same other disadvantages mentioned above with respect to the single-port SRAM cell 10, as well as additional disadvantages occasioned by the additional circuitry that is needed to drive and read additional word lines and bit lines.

### BRIEF DESCRIPTION

According to one aspect of the present invention, a static random-access memory (SRAM) cell includes a non-inverting logic element having an input and an output. A vertical resistor feedback device is connected between the output and the input of the non-inverting logic element.

According to another aspect of the present invention, the SRAM cell includes a write-enable transistor having a first source/drain terminal connected to the input of the non-inverting logic element, and a read-enable transistor having a first source/drain terminal connected to the output of the non-inverting logic element.

According to another aspect of the present invention, the write-enable transistor has a gate coupled to a write word line in an array of SRAM memory cells and a second source/drain terminal connected to a write bit line in the array of SRAM memory cells, and the read-enable transistor has a gate coupled to a read word line in the array of SRAM memory cells and a second source/drain terminal connected to a read bit line in the array of SRAM memory cells.

According to another aspect of the present invention, the non-inverting logic element is a first inverter having an input and an output, and a second inverter having an input and an output, the input connected to the output of the first inverter.

According to another aspect of the present invention, single-port and dual-port SRAM cells each employ a vertical resistor device for improved SEU immunity.

According to another aspect of the invention, the vertical resistor device may be formed as an unprogrammed antifuse device, a virgin ReRAM device, a high resistance contact device or other similar vertical resistor device.

### BRIEF DESCRIPTION OF THE DRAWING FIGURES

The invention will be explained in more detail in the following with reference to embodiments and to the drawing in which are shown:

FIG. 1 is a schematic diagram of a prior-art single port SRAM cell;

FIG. 2 is a schematic diagram of a prior-art dual-port SRAM cell;

FIG. 3 is a schematic diagram of a dual-port SRAM cell employing a vertical resistor feedback device in accordance with aspects of the present invention;

FIG. 4 is a schematic diagram of a single port SRAM cell employing a vertical resistor device for improved SEU immunity in accordance with an aspect of the invention; and

FIG. 5 is a schematic diagram of a dual port SRAM cell employing a vertical resistor device for improved SEU immunity in accordance with an aspect of the invention.

FIG. 6 is a cross-sectional view of a typical antifuse device structure that may be employed as a vertical resistor in embodiments of the present invention;

FIG. 7 is a cross-sectional view of a typical virgin ReRAM device structure that may be employed as a vertical resistor in embodiments of the present invention; and

FIG. 8 is a cross-sectional view of another typical high-resistance structure that may be employed as a vertical resistor in embodiments of the present invention.

### DETAILED DESCRIPTION

Persons of ordinary skill in the art will realize that the following description of the present invention is illustrative only and not in any way limiting. Other embodiments of the invention will readily suggest themselves to such skilled persons.

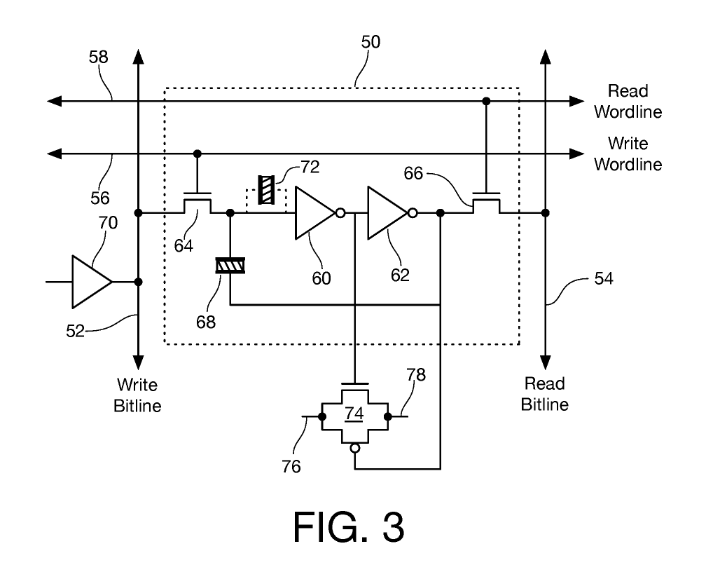

Referring now to FIG. 3, a schematic diagram shows a 2-port SRAM cell 50 in accordance with an aspect of the present invention. SRAM cell 50 is coupled to a write bit line 52 and a read bit line 54 and to a write word line 56 and a read word line 58.

The 2-port SRAM cell 50 is formed from a non-inverting logic element. In FIG. 3, the non-inverting logic element is depicted as two inverters 60 and 62 connected in series. A write-select transistor 64 is connected between the input of inverter 60 and the write bit line 52. The gate of the write-select transistor 64 is connected to write word line 56. A read-select transistor 66 is connected between the output of inverter 62 and the read bit line 54. The gate of the read-select transistor 66 is connected to read word line 58.

A vertical resistor feedback device 68 is connected between the output of inverter 62 and the input of inverter 60. This vertical resistor feedback device 68 is very useful in that it provides an extremely high impedance while taking up almost no layout area on the integrated circuit because it can be fabricated on an existing contact or inter-metal via in the integrated circuit structure.

When the voltages at both write word line 56 and read word line 58 are at 0V, write-select transistor 64 and read-select transistor 66 are turned off and the SRAM cell 50 is isolated from the write bit line 52 and the read bit line 54. In this condition, the state of the output of inverter 62 is fed back to the input of the inverter 60 through the high impedance connection provided by vertical resistor feedback device 68. The input of the first inverter is a MOS transistor gate and presents a very high impedance input as will be appreciated by persons of ordinary skill in the art. This stabilizes the state of the SRAM cell 50.

To write to SRAM cell 50, a data bit to be written is presented on write bit line 52 through a write-bit line driver 70 and a logic high level is presented on the write word line 56. This turns on write-select transistor 64. The write-bit line driver 70 supplying the data to write bit line 52 can be a standard line-driving buffer that easily overcomes the high-impedance data supplied to the input of inverter 60 by vertical resistor feedback device 68 and forces the input of inverter 60 to the logic level of the data present on write bit line 52. This, in turn forces the output of inverter 62 to the logic level of the data present on write bit line 52. When write-select transistor 64 is turned off, the state of the SRAM cell 50 is stabilized at the data value that was presented to the input of inverter 60 during the time that the write-select transistor 64 was in its on state by the feedback of vertical resistor device 68.

To read from SRAM cell 50, a logic high level is presented on the read word line 58. This turns on read-select transistor 66, presenting the data present at the output of inverter 60 onto read bit line 54.

The use of the vertical resistor feedback device 68 provides the SRAM cell 50 with some degree of immunity to single event upset (SEU) events. The SRAM memory cell 50 may be provided with improved immunity to SEU events by employing a second vertical resistor device (shown in dashed lines 72) connected between the return path of vertical resistor feedback device 68 and the input of inverter 60. Since SEU events affect transistor source/drain diffusions and not transistor gates, positioning the second vertical resistor device 72 between the right-hand source/drain diffusion of write-select transistor 64 and the gates of the transistors forming the inverter 60, any glitch at the write-select transistor 64 will likely have a duration shorter than the RC time constant of the resistance of the second vertical resistor device 72 and the gate capacitance of the two transistors forming the inverter 60.

In one embodiment of the invention, the SRAM cell 50 may be used as a configuration memory in a user-configurable integrated circuit in which it is disposed. In such an embodiment, SRAM cell 50 is shown in FIG. 3 driving an external CMOS passgate switch 74 that may be used to connect together programmable circuit nodes connected at reference numerals 76 and 78.

The SRAM cell 50 requires six transistors, two each for inverters 60 and 62 in addition to the read-select transistor 64 and the write-select transistor 66. An array of SRAM cells 50 requires a write bit line 52 and a read bit line 54 per column, and a write word line 56 and a read word line 58 per row.

In accordance with another aspect of the present invention, the SRAM cell 50 of FIG. 3 can be made more radiation tolerant and better protected from single event upset (SEU) events by adding a second virgin SEU inhibit vertical resistor device 72 (shown in FIG. 3 in phantom lines) coupled between the input of inverter 60 and the common node of the write-select transistor 64 and the vertical resistor feedback device 68. The RC-time constant (the product of the resistance of the SEU inhibit vertical resistor device 72 and the gate capacitance of the input to inverter 60) should be higher than the duration of an SEU event, meaning that the SEU event is too short to flip the states of inverters 60 and 62 and the SRAM cell 50 will hold its state over an SEU event, which can only occur at source/drains (e.g., diffusions of write-select transistor 64 or the read-select transistor 66), not at gates. Such SEU immunity is obtained at the expense of the write speed of the SRAM cell 50, since the write pulse must be applied for a period longer than the aforementioned time constant of the resistance of virgin SEU inhibit vertical resistor device 72 and the gate capacitance of the input to inverter 60. In applications such as where the SRAM cell 50 is employed as a configuration memory in a user-configurable circuit, this additional programming overhead is not problematic.

The design window for SRAM cell 50 is robust. The write-bit line driver 70 driving the write bit line 52 may have a drive level that will easily be able to overdrive high-resistive vertical resistor feedback device 68 to overcome the weak logic level at the output of vertical resistor feedback device 68. In addition, the write-bit line driver 70 does not compete against the output of the inverter 62 in the SRAM cell. Because of this fact, the inverter 62 can be made stronger to drive the read bit line 54 to the proper level more quickly despite the capacitance of the read bit line 54. In addition, the output of SRAM cell 50 is single ended, allowing for a simpler single-bitline sense-amplifier and driver, and may eliminate the need to pre-charge the bit line for read operations.

The 2-port SRAM cell 50 of FIG. 3 employs six transistors, two fewer than traditional eight-transistor dual-port SRAMs such as SRAM 30 depicted in FIG. 2. SRAM cell 50 employs two bit lines and two word lines instead of the four word lines that are used in SRAM 30.

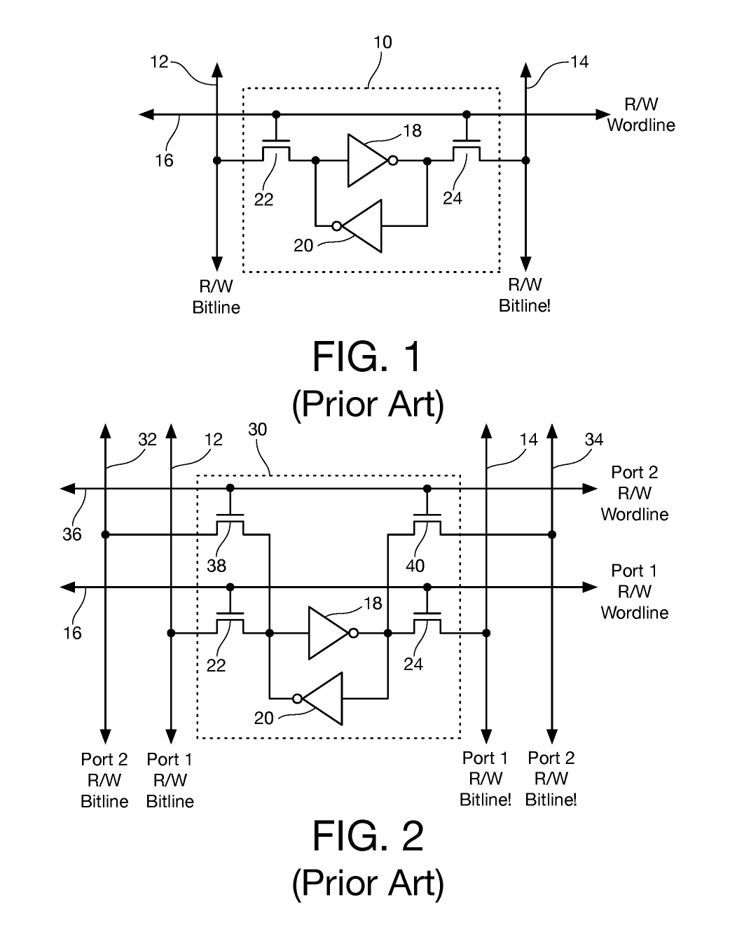

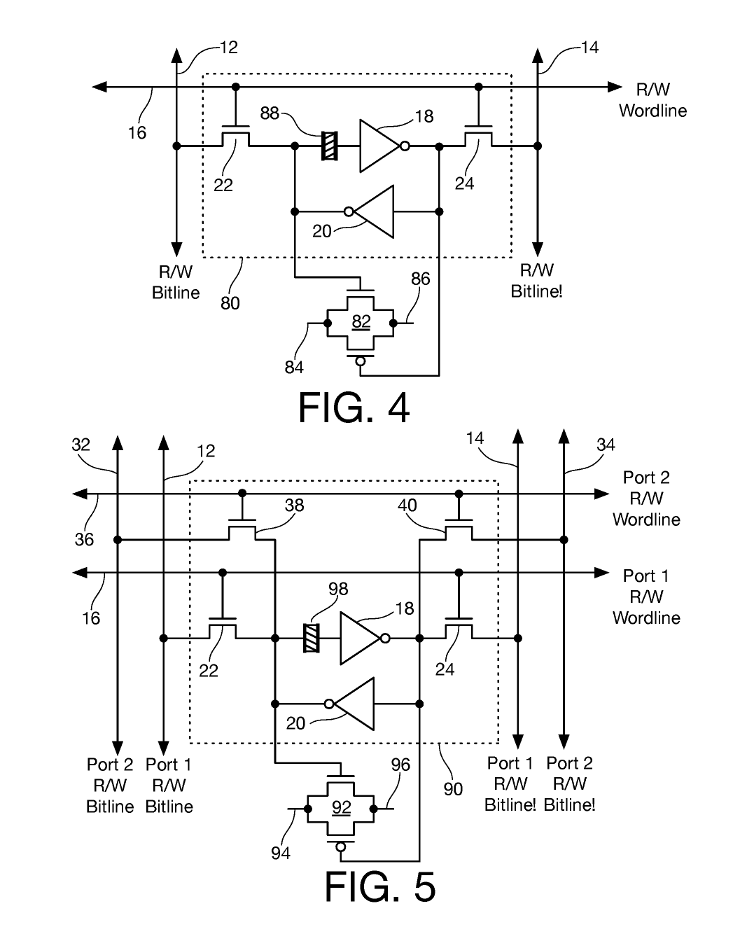

Referring now to FIG. 4, a single-port SRAM cell 80 in accordance with another aspect of the present invention employs a vertical resistor feedback device for improved SEU immunity in accordance with an aspect of the invention. SRAM cell 80 is similar to the prior-art single port SRAM cell 10 of FIG. 1 in that it includes some of the same circuit elements as SRAM cell 10. Circuit elements of SRAM cell 80 that are present in SRAM cell 10 of FIG. 1 will be designated using the same reference numerals used to designate the corresponding circuit elements in FIG. 1.

The SRAM cell 80 is coupled to a pair of complementary read-write (R/W) bit lines 12 and 14 and to a R/W word line 16.

The single port SRAM cell 80 is formed from two inverters 18 and 20 arranged in a feedback configuration where the output of inverter 18 is coupled to the input of inverter 20 through a vertical resistor feedback device 88. The output of inverter 20 is coupled to the input of inverter 18.

A first access transistor 22 is connected between R/W bit line 12 and the common connection of the vertical resistor feedback device 88 and the output of inverter 20. The first access transistor 22 has its gate connected to the R/W word line 16. A second access transistor 24 is connected between R/W bit line 14 and the common connection of the input of inverter 20 and the output of inverter 18. The second access transistor 24 has its gate connected to the R/W word line 16.

In one embodiment of the invention, the SRAM cell 80 may be used as a configuration memory in a user-configurable integrated circuit in which it is disposed. In such an embodiment, the SRAM cell 80 is shown in FIG. 4 driving an external CMOS passgate switch 82 that may be used to connect together programmable circuit nodes connected at reference numerals 84 and 86.

The SRAM cell 80 of FIG. 4 employs the vertical resistor feedback device 88 for improved SEU immunity in accordance with an aspect of the invention. As indicated above the vertical resistor feedback device 88 is connected between the return path from the output of inverter 20 and the input of inverter 18. Since SEU events affect transistor source/drain diffusions and not transistor gates, positioning the vertical resistor feedback device 88 between the right-hand source/drain diffusion of select transistor 22 and the gates of the transistors forming the inverter 18, any glitch at the select transistor 22 (as well as any glitch at the select transistor 24 coupled through inverter 20) will likely have a duration shorter than the RC time constant of the resistance of the vertical resistor feedback device 88 and the gate capacitance of the two transistors forming the inverter 18.

FIG. 5 is a schematic diagram of a dual-port SRAM cell 90 employing a vertical resistor feedback device for improved SEU immunity in accordance with an aspect of the invention. SRAM cell 90 is similar to the prior-art dual-port SRAM cell 30 of FIG. 2 in that it includes some of the same circuit elements as SRAM cell 30. Circuit elements of SRAM cell 90 that are present in SRAM cell 30 of FIG. 2 will be designated using the same reference numerals used to designate the corresponding circuit elements in FIG. 2.

SRAM cell 90 is coupled to a first pair of complementary read-write (R/W) bit lines 12 and 14 responsive to a R/W word line 16 through first and second access transistors 22 and 24. In addition SRAM cell 30 is coupled to a second pair of complementary read-write (R/W) bit lines 32 and 34 and responsive to a second R/W word line 36 through third and fourth access transistors 38 and 40, respectively.

SRAM cells 90 can employ two R/W ports (dual port) or one read port and one write port (2-port). Both of these configurations use the same SRAM cell 90, and differ only in that they require different access circuits to drive the bit lines 12, 14, 32, and 34 and word lines 16 and 36 to write and read data. The read and write operations are the same as the read and write operations for SRAM cell 30 of FIG. 2.

In one embodiment of the invention, the SRAM cell 90 may be used as a configuration memory in a user-configurable integrated circuit in which it is disposed. In such an embodiment, SRAM cell 90 is shown in FIG. 5 driving an external CMOS passgate switch 92 that may be used to connect together programmable circuit nodes connected at reference numerals 94 and 96.

The SRAM cell 90 of FIG. 5 employs a vertical resistor feedback device 98 for improved SEU immunity in accordance with an aspect of the invention. The vertical resistor feedback device 98 is connected between the return path from the output of inverter 20 and the input of inverter 18. Since SEU events affect transistor source/drain diffusions and not transistor gates, positioning the vertical resistor feedback device 98 between the right-hand source/drain diffusion of select transistors 22 and 38 and the gates of the transistors forming the inverter 18, any glitch at the select transistors 22 and 38 (as well as any glitch at the select transistors 24 and 40 coupled through inverter 20) will likely have a duration shorter than the RC time constant of the resistance of the vertical resistor feedback device 98 and the gate capacitance of the two transistors forming the inverter 18.

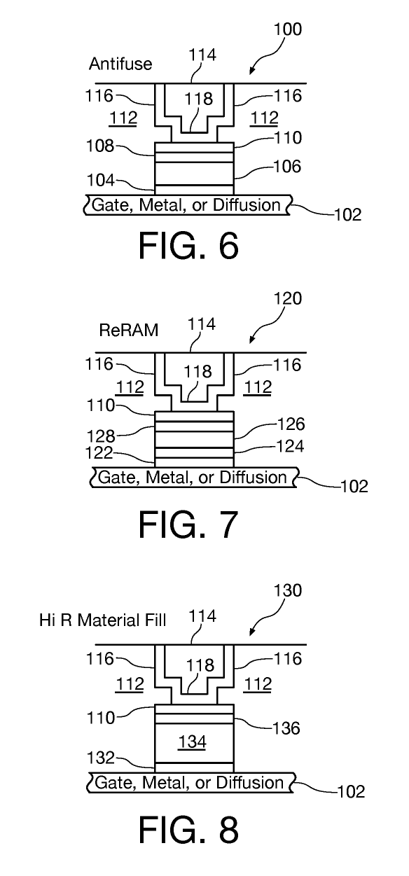

Referring now to FIG. 6, a cross-sectional view shows a typical unprogrammed antifuse device structure 100 that may be employed as one form of a vertical resistor in embodiments of the present invention. The unprogrammed antifuse 100 is formed over one of a transistor gate, metal interconnect layer, or diffusion in a substrate or well (shown as layer 102). Layer 104 is a lower electrode of the antifuse, layer 106 is a layer of antifuse material formed over the lower electrode 104 and which may be formed from a material such as doped or undoped amorphous silicon. An upper electrode 108 is formed over the antifuse material 106. The layers 104, 106, and 108 may then be etched as a stack. In some embodiments, layer 102 may be used as an etch stop layer and in other embodiments a separate etch-stop layer (not shown) may be formed over layer 102. In some embodiments, an additional diffusion barrier layer 110 for an upper layer of metal is also formed on and etched with the stack.

A dielectric layer 112 is then formed over the stack of layers 104, 106, and 108 and a metal layer is formed and connected to the top layer (110 or 108) of the stack. In FIG. 18, the metal layer is shown as a damascene copper layer 114 surrounded by a liner 116 as is known in the art. Prior to formation of the liner 116 and the copper metal line 114, a via 118 is formed to make connection to the top layer 108 or 110 of the antifuse as is known in the art.

Antifuse structures such as the one described above are well known. One non-limiting illustrative example of an antifuse 100 is shown in U.S. Pat. No. 5,770,885, the entire contents of which are incorporated herein by reference. The antifuse 100 remains unprogrammed, and in this state has a resistance on the order of from about 1 M ohm to greater than about 1 G ohm.

Referring now to FIG. 7, a cross-sectional view shows a typical virgin ReRAM device structure 120 that may be employed as another form of a vertical resistor in embodiments of the present invention. A “virgin” ReRAM device 120, is identical in every way to a conventional ReRAM device except there is no way to program or erase it so it always remains in the fully erased state in which it was when fabricated. This is a high impedance state, where its resistance is field dependent but is greater than about 10 MΩ and generally about 1 GΩ. This form of a vertical resistor 62 is very useful in that it provides an extremely high impedance while taking up almost no layout area on the integrated circuit because it can be fabricated on an existing contact or inter-metal via in the integrated circuit structure. The polarity of the ReRAM device 62 does not matter. One non-limiting example of a ReRAM device is described in U.S. Pat. No. 8,415,650 issued Apr. 9, 2013, the entire contents of which are incorporated herein by reference.

As shown in FIG. 7 to which attention is now directed, a ReRAM device is basically two metal plates separated by a solid electrolyte layer. The ReRAM device normally can be programmed by applying a voltage potential having a polarity that will drive metal ions from one of the metal plates into the solid electrolyte layer and erased by applying a voltage potential having a polarity that will drive the metal ions back to the source metal plate.

Some of the structure shown in the embodiment of FIG. 7 is similar to some of the structure depicted in FIG. 6. Accordingly, elements present in FIG. 7 that correspond to elements in FIG. 6 will be designated using the same reference numerals as used in FIG. 6.

An unprogrammed (“virgin”) ReRAM device 120 is formed over one of a transistor gate, metal interconnect layer, or diffusion in a substrate or well (shown as layer 102). Layer 102 is a diffusion barrier and/or adhesion layer. Layer 104 is a lower electrode of the virgin ReRAM device 120. Layer 126 is a solid electrolyte layer formed over the lower electrode 124. An upper electrode 128 is formed over the solid electrolyte layer 136. In some embodiments, a diffusion barrier layer 110 is also formed on and etched with the stack. The layers 122, 124, 126, 128, and 110 (if present) may then be etched as a stack. In some embodiments, layer 102 may be used as an etch stop layer and in other embodiments a separate etch-stop layer (not shown) may be formed over layer 102.

As in the embodiment of FIG. 6, a dielectric layer 112 is then formed over the stack of layers 122, 124, 126, 128 and 110 and a metal layer is formed and connected to the top layer (110 or 128) of the stack. In FIG. 7, the metal layer is shown as a damascene copper layer 114 surrounded by a liner 116 as is known in the art. Prior to formation of the liner 116 and the copper metal line 114, a via 118 is formed to make connection to the top layer 128 or 110 of the virgin ReRAM device structure 120 as is known in the art.

ReRAM structures such as the one described above are well known. One non-limiting illustrative example of an ReRAM device structure 120 is shown in U.S. Pat. No. 8,415,650, the entire contents of which are incorporated herein by reference. The ReRAM device 120 remains unprogrammed, and in this state has a resistance on the order of from about 1 M ohm to greater than about 1 G ohm.

Referring now to FIG. 8, a cross-sectional view shows another typical high-resistance structure that may be employed as a vertical resistor in embodiments of the present invention. Some of the structure shown in the embodiment of FIG. 8 is similar to some of the structure depicted in FIG. 6 and FIG. 7 Accordingly, elements present in FIG. 8 that correspond to elements in the embodiments of FIG. 6 and FIG. 7 will be designated using the same reference numerals as used in those drawing figures.

A high-resistance structure 130 is formed over one of a transistor gate, metal interconnect layer, or diffusion in a substrate or well (shown as layer 102). Layer 132 is a diffusion barrier and/or adhesion layer. Layer 134 is layer of high-resistance material formed over layer 1432. A second diffusion barrier layer 136 is formed over the layer of high-resistance material 134. In some embodiments, a second diffusion barrier layer 110 is also formed on and etched with the stack. The layers 132, 134, 136, and 110 (if present) may then be etched as a stack. In some embodiments, layer 102 may be used as an etch stop layer and in other embodiments a separate etch-stop layer (not shown) may be formed over layer 102.

As in the embodiment of FIG. 6 and FIG. 7, a dielectric layer 112 is then formed over the stack of layers 132, 134, 136, and 112 and a metal layer is formed and connected to the top layer (110 or 136) of the stack. In FIG. 8, the metal layer is shown as a damascene copper layer 114 surrounded by a liner 116 as is known in the art. Prior to formation of the liner 116 and the copper metal line 114, a via 118 is formed to make connection to the top layer 136 or 110 of the virgin ReRAM device as is known in the art.

Numerous materials may be employed to form the high-resistance layer 134. A non-exhaustive list includes silicon-rich SiO₂, tantalum-rich Ta₂O₅, titanium-rich TiO₂, aluminum-rich Al₂O₃, silicon-rich SiN. Such films can be formed using CVD, PECVD and other deposition processes. Other process-compatible stable high-resistance materials will readily suggest themselves to persons of ordinary skill in the art. The thicknesses and chemical compositions of these materials and the deposition conditions necessary to deposit them to produce desired values of resistance can be easily determined experimentally for employment in particular embodiments of the present invention. These design parameters are easily tailored by persons of ordinary skill in the art to achieve a resistance value of from about 1 M ohm to greater than 1 G ohm.

Persons of ordinary skill in the art will appreciate that, while a damascene copper metallization structure is shown in FIGS. 6-8, other types of metallization layers may be employed instead. Such skilled persons will readily understand how to integrate such other metallization schemes into the present invention.

Persons of ordinary skill in the art will appreciate that the drawing figures show the vertical resistors all oriented in the same polarity. Such skilled persons will appreciate that, since the devices will never be programmed, in any of the circuits disclosed herein the orientation of the ReRAM devices does not matter and they can be oriented in whatever manner best suits the layout and design.

While embodiments and applications of this invention have been shown and described, it would be apparent to those skilled in the art that many more modifications than mentioned above are possible without departing from the inventive concepts herein. The invention, therefore, is not to be restricted except in the spirit of the appended claims

What is claimed is:

1. A static random-access memory (SRAM) cell comprising:
a non-inverting logic element having an input and an output;
a vertical resistor feedback device connected between the output and the input of the non-inverting logic element.

2. The SRAM cell of claim 1, further comprising:
a write-enable transistor having a first source/drain terminal connected to the input of the non-inverting logic element; and
a read-enable transistor having a first source/drain terminal connected to the output of the non-inverting logic element.

3. The SRAM cell of claim 1 wherein the vertical resistor feedback device is formed as an unprogrammed antifuse.

4. The SRAM cell of claim 1 wherein the vertical resistor feedback device is formed as a virgin ReRAM device.

5. The SRAM cell of claim 1 wherein the vertical resistor feedback device is formed as a layer of a high-resistance metal compound.

6. The SRAM cell of claim 2 wherein:
the write-enable transistor has a gate coupled to a write word line in an array of SRAM memory cells and a second source/drain terminal connected to a write bit line in the array of SRAM memory cells; and
the read-enable transistor has a gate coupled to a read word line in the array of SRAM memory cells and a second source/drain terminal connected to a read bit line in the array of SRAM memory cells.

7. The SRAM cell of claim 1 wherein the non-inverting logic element comprises:
a first inverter having an input and an output; and
a second inverter having an input and an output, the input of the second inverter connected to the output of the first inverter.

8. The SRAM cell of claim 7, further comprising:
a write-enable transistor having a first source/drain terminal connected to the input of the first inverter; and
a read-enable transistor having a first source/drain terminal connected to the output of the second inverter.

9. The SRAM cell of claim 7, further comprising:
an SEU inhibit vertical resistor device connected between the input of the non-inverting logic element and a common node connecting the vertical resistor feedback device and the write-select transistor.

10. The SRAM cell of claim 9 wherein the SEU inhibit vertical resistor device is formed as an unprogrammed antifuse.

11. The SRAM cell of claim 9 wherein the SEU inhibit vertical resistor device is formed as a virgin ReRAM device.

12. The SRAM cell of claim 9 wherein the SEU inhibit vertical resistor device is formed as a layer of a high-resistance metal compound.

13. The SRAM cell of claim 7 wherein:
the write-enable transistor has a gate coupled to a write word line in an array of SRAM memory cells and a second source/drain terminal connected to a write bit line in the array of SRAM memory cells; and
the read-enable transistor has a gate coupled to a read word line in the array of SRAM memory cells and a second source/drain terminal connected to a read bit line in the array of SRAM memory cells.

14. A method of writing a data bit to a static random-access memory (SRAM) cell having a high impedance input node holding a logic level through high-impedance feedback loop from an output node, the method comprising:
coupling a data bit into the input node from a data source having a drive level drive sufficient to overdrive the high-impedance input node and the high-impedance feedback loop; and
decoupling the data source from the input node.

15. The method of claim 14 wherein coupling the data bit into the input node from a write-bit line driver having a drive level drive sufficient to overdrive the high-impedance input node and the high-impedance feedback loop comprises coupling the data bit into the input node through a write-select transistor.

16. A static random-access memory (SRAM) cell comprising:
a non-inverting logic element having an input and an output;
at least one select transistor coupled to the input of the non-inverting logic element;
an SEU inhibit vertical resistor device connected between the input of the non-inverting logic element and a common node connecting the output of the non-inverting logic element and the select transistor.

17. The SRAM cell of claim 16 wherein the SEU inhibit vertical resistor device is formed as an unprogrammed antifuse.

18. The SRAM cell of claim 16 wherein the SEU inhibit vertical resistor device is formed as a virgin ReRAM device.

19. The SRAM cell of claim 16 wherein the SEU inhibit vertical resistor device is formed as a layer of a high-resistance metal compound.

20. A static random-access memory (SRAM) cell of claim 16 wherein;
the non-inverting logic element comprises:
a first inverter having an input and an output; and
a second inverter having an input and an output, the input of the second inverter connected to the output of the first inverter;
the at least one select transistor is coupled to the input of the first inverter; and
the SEU inhibit vertical resistor device is connected between the input of the first inverter and a common node connecting the output of the second inverter and the at least one select transistor.
